(19) United States
(12) Patent Application Publication
(10) Pub. No.: US 2017/0098399 A1
(43) Pub. Date: Apr. 6, 2017

(54) ARRAY SUBSTRATE AND FABRICATING METHOD THEREOF, AND METHOD AND DEVICE FOR TESTING ELIGIBILITY OF DATA LINE

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventor: Bo ZHANG, Beijing (CN)

(21) Appl. No.: 15/128,168

(22) PCT Filed: Feb. 16, 2016
(86) PCT No.: PCT/CN2016/073849

§ 371 Date: Sep. 22, 2016

(30) Foreign Application Priority Data
Mar. 3, 2015 (CN) 201510094570.6

(51) Int. Cl. G09G 3/00; G01R 31/02; H01L 27/12

(52) U.S. Cl. CPC G09G 3/006; H01L 27/1262; H01L 27/124; G01R 31/021

(57) ABSTRACT

The present disclosure provides for a method for fabricating an array substrate. The method includes forming a continuous and complete annular common electrode pattern surrounding a pixel.

### CROSS-REFERENCES TO RELATED APPLICATIONS

This application is a National Stage entry of PCT/CN2016/073849 filed Feb. 16, 2016, which claims the benefit and priority of Chinese Patent Application No. 201510094570.6, filed on Mar. 3, 2015, both of which are incorporated herein by reference in their entirety.

### BACKGROUND

Exemplary embodiments of the present disclosure relate to an array substrate and a fabricating method thereof, and a corresponding method and device for testing eligibility of a data line.

In the fabricating process of an array substrate, there is a need to test whether the line resistance of the formed data line is eligible. A testing method in the prior art is to fabricate metal testing lines while fabricating the array substrate. The metal testing lines are drawn from a data driving circuit, and are extending to the opposite side of the data driving circuit via an edge region outside a sealant region in a panel. A voltage drop of the metal testing line is determined by measuring voltages at the ends of the metal testing lines at the opposite side of the data driving circuit. Further, a voltage drop of the data lines may be obtained through simulation, while it can be determined whether the line resistance of the data lines is eligible. Since an annular common electrode pattern is usually disposed below the sealant region, there is a need for an opening that is disposed at the corner of the annular common electrode pattern away from the data driving circuit, so that the metal testing lines disposed at the edge region can be introduced into a pixel region at the opposite side of the data driving circuit.

As shown in FIG. 1, which shows a structural diagram of an array substrate fabricated by an array substrate fabricating method in the prior art in one panel before the sealant is formed, the array substrate includes a pixel region A-A, an annular common electrode pattern 1 surrounding the pixel region A-A, and metal testing lines 2 formed outside the common electrode pattern 1. An opening is provided at a corner of the common electrode pattern 1, via which the metal testing lines 2 are introduced into the pixel region A-A.

In the process of applying sealant to the array substrate in FIG. 1, there is a need to perform laser irradiation on the sealant for solidation. At the opening, since the reflectivity of the metal testing lines is higher than that in other region within the opening position, and the cooling rate of the metal testing lines is different from the sealant, the solidation speed and the cooling rate of the sealant at the metal testing lines and the sealant at the place without metal testing line are different, resulting in package failure.

On the other hand, after completion of packaging, there is a need to cut the array substrate to obtain respective separate panels. During the cutting, the metal testing lines 2 disposed at the right side of the common electrode pattern 1 are cut off, so that the metal testing lines 2 below the cutting line are exposed. During a subsequent reliability test, the exposed metal testing lines will electrochemically corrode, eventually leading to the corrosion of the sealant around it, which will also lead to package failure.

### BRIEF DESCRIPTION

According to an exemplary embodiment of the present disclosure, there is provided an array substrate and a fabricating method thereof, and a corresponding method and device for testing eligibility of a data line. The test on eligibility of array substrate data lines can be achieved without providing metal testing lines, so as to fundamentally avoid the problem of package failure caused by the metal testing lines.

According to a first aspect of the present disclosure, there is provided a method for fabricating an array substrate, including forming a continuous and complete annular common electrode pattern surrounding a pixel region.

According to an exemplary embodiment of the present disclosure, forming a continuous and complete annular common electrode pattern surrounding a pixel region includes forming the continuous and complete annular common electrode pattern while forming a data line pattern of the array substrate in the same layer.

According to an exemplary embodiment of the present disclosure, forming the continuous and complete annular common electrode pattern while forming a data line pattern of the array substrate in the same layer includes depositing a metal electrode layer, and forming the data line pattern and the continuous and complete annular common electrode pattern by performing one-time patterning process on the metal electrode layer.

According to an exemplary embodiment of the present disclosure, depositing a metal electrode layer includes depositing metal material by a sputtering process.

According to an exemplary embodiment of the present disclosure, the method for fabricating an array substrate further includes coating photoresist on the metal electrode layer, and exposing and developing the photoresist with a mask plate.

According to an exemplary embodiment of the present disclosure, the mask plate is not transparent or not completely transparent at the positions corresponding to the data line pattern and the continuous and complete annular common electrode pattern.

According to an exemplary embodiment of the present disclosure, forming the data line pattern and the continuous and complete annular common electrode pattern by performing one-time patterning process on the metal electrode layer includes etching the metal electrode layer in the periphery of the continuous and complete annular common electrode pattern in the same-time patterning process.

According to a second aspect of the present disclosure, there is proposed an array substrate, including a pixel region; and a continuous and complete annular common electrode pattern surrounding the pixel region.

According to an exemplary embodiment of the present disclosure, the array substrate further includes a data line pattern, wherein the data line pattern and the continuous and complete annular common electrode pattern are formed in the same layer.

According to an exemplary embodiment of the present disclosure, the array substrate further includes a metal electrode layer, wherein the data line pattern and the continuous and complete annular common electrode pattern are formed on the metal electrode layer by a one-time patterning process.

According to an exemplary embodiment of the present disclosure, the array substrate further includes a photoresist layer coated on the metal electrode layer.

According to a third aspect of the present disclosure, there is provided a method for testing eligibility of a data line of the array substrate mentioned above. This method includes lighting a first pixel nearest to a data driving circuit according to a first preset data voltage, and lighting a second pixel farthest from the data driving circuit according to a second preset data voltage, wherein the first pixel and the second pixel are both connected to the tested data line, obtaining the luminance of the first pixel and the luminance of the second pixel, determining whether the actual luminance difference between the luminance of the first pixel and the luminance of the second pixel is larger than a preset luminance difference, and determining that the tested data line is ineligible when the actual luminance difference is larger than the preset luminance difference.

According to an exemplary embodiment of the present disclosure, the magnitude of the first preset data voltage is equal to the magnitude of the second preset data voltage.

According to an exemplary embodiment of the present disclosure, the preset luminance difference corresponds to the first preset data voltage and the second preset data voltage.

According to an exemplary embodiment of the present disclosure, the first pixel and the second pixel comprise the same number of sub-pixels.

According to a fourth aspect of the present disclosure, there is provided a device for testing eligibility of a data line of the array substrate mentioned above. The device includes a lighting module for lighting a first pixel nearest to a data driving circuit according to a first preset data voltage, and lighting a second pixel farthest from the data driving circuit according to a second preset data voltage the first pixel and the second pixel are correspondingly connected to the same tested data line, a lighting module arranged to light a first pixel nearest to a data driving circuit according to a first preset data voltage, and light a second pixel farthest from the data driving circuit according to a second preset data voltage, wherein the first pixel and the second pixel are both connected to the tested data line, an obtaining module arranged to obtain the luminance of the first pixel and the luminance of the second pixel, and a determination module arranged to determine whether the actual luminance difference between the luminance of the first pixel and the luminance of the second pixel is larger than a preset luminance difference, and determine that the tested data line is ineligible when the actual luminance difference is larger than the preset luminance difference.

According to an exemplary embodiment of the present disclosure, the magnitude of the first preset data voltage is equal to the magnitude of the second preset data voltage.

According to an exemplary embodiment of the present disclosure, the preset luminance difference corresponds to the first preset data voltage and the second preset data voltage.

According to an exemplary embodiment of the present disclosure, the first pixel and the second pixel comprise the same number of sub-pixels.

According to an exemplary embodiment of the present disclosure, the obtaining module is a photosensitive detecting device.

### BRIEF DESCRIPTION OF THE DRAWINGS

In order to more clearly illustrate the technical solutions in embodiments of the present disclosure or in the prior art, the following drawings to be used in the description of the embodiments or in the prior art will be briefly introduced below. Apparently, the drawings in the following description are only for some embodiments of the present disclosure, those of ordinary skill in the art may also obtain other drawings from these drawings, without creative efforts.

FIG. 1 is a schematic diagram of the structure of an array substrate in the prior art;

FIG. 2 is a schematic flowchart of the method for testing eligibility of a data line according to an embodiment of the present disclosure;

FIG. 3 is a schematic diagram of the structure of an array substrate fabricated by the fabricating method provided in the embodiment of the present disclosure; and

FIG. 4 is a schematic diagram of the structure of a device for testing eligibility of a data line according to an embodiment of the present disclosure.

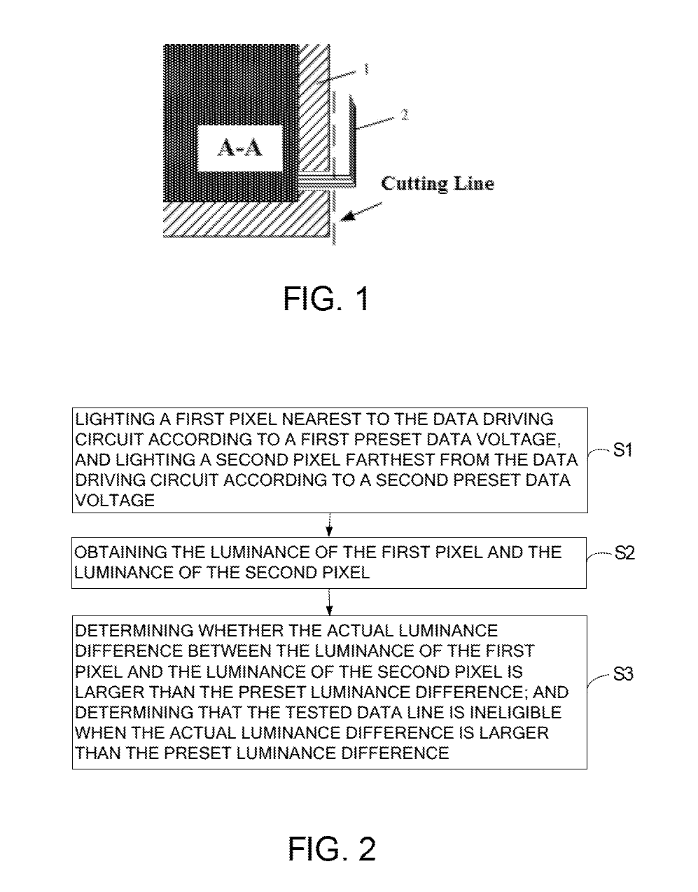

### DETAILED DESCRIPTION

The technical solution in embodiments of the present disclosure will be clearly and completely described in combination with the drawings in the embodiments of the present disclosure. Apparently, the described embodiments are merely part of the embodiments of the present disclosure, instead of all the embodiments. Based on the embodiments of the present disclosure, all other embodiments obtained by those of ordinary skill in the art without creative work fall within the scope of the present disclosure.

In the description of the present disclosure, it should be noted that the orientation or position relations indicated by the terms “upper”, “lower”, “top”, “bottom” and the like are orientation or position relations based on the drawings. They are only used for facilitating and simplifying the description of the present disclosure, rather than indicating or implying that the indicated devices or elements must have a specific orientation and are constructed and operated in a specific orientation, and therefore cannot be construed as limiting the present disclosure.

Further, in the present disclosure, the terms “first”, “second”, “third” are for descriptive purposes only, not to be construed to indicate or imply relative importance. The term “a plurality of” refers to two or more, unless otherwise expressly limited.

According to an exemplary embodiment of the present disclosure, there is provided a method for testing eligibility of a data line of the array substrate in the embodiment of the present invention, and as shown in FIG. 2, the method may include:

Step S1, lighting a first pixel nearest to a data driving circuit according to a first preset data voltage, and lighting a second pixel farthest from the data driving circuit according to a second preset data voltage, wherein the first pixel and the second pixel are both connected to the tested data line;

Step S2, obtaining the luminance of the first pixel and the luminance of the second pixel; and

Step S3, determining whether the actual luminance difference between the luminance of the first pixel and the luminance of the second pixel is larger than a preset luminance difference; and determining that the tested data line is ineligible when the actual luminance difference is larger than the preset luminance difference.

According to an exemplary embodiment of the present disclosure, the first preset data voltage and the second preset data voltage are respectively used to light one pixel nearest to and another pixel farthest from a data driving circuit, wherein the two pixels are both connected to the tested data line. If the luminance difference between the two pixels is larger than a preset value, it indicates that the line resistance of the data line is too large, and the data line is ineligible. In addition, if it is determined that the luminance difference between the two pixels is less than or equal to the preset value, it indicates that the line resistance of the data line can basically satisfied the requirement for uniform light-emitting of a display panel, and it is determined now that the tested data line is eligible.

According to the method of an exemplary embodiment of the present disclosure, the eligibility test on the data line can be completed without using a metal testing line. Thus, the problem of package failure caused by the metal testing line can be fundamentally avoided.

In an embodiment, the first preset data voltage and the second preset data voltage in the step S1 described above may be provided as needed. Accordingly, the preset luminance difference should correspond to the first preset data voltage and the second preset data voltage.

Alternatively, the first preset voltage and the second preset voltage may be set as a larger data voltage, such that the first pixel and the second pixel can display large luminance for facilitating the detection and determination.

In an embodiment, it may be set that the value of the first preset voltage is equal to the value of the second preset voltage. Therefore, it can reduce the complexity of setting the preset luminance difference.

The first pixel herein may include a plurality of sub-pixels, and the second pixel may also include the same number of sub-pixels.

In the above-described step S2, the luminance of the first pixel and the luminance of the second pixel may be detected by using a photosensitive detecting device.

According to another exemplary embodiment of the present disclosure, there is provided a method for fabricating an array substrate, and the method for testing eligibility of a data line described above may be applicable to an array substrate fabricated by the fabricating method provided according to the embodiment of the present disclosure.

Specifically, the method for fabricating an array substrate includes forming a continuous and complete annular common electrode pattern surrounding a pixel region. That is, the continuous and complete annular common electrode pattern closes at respective corners of one side away from the data driving circuit (it is unnecessary to provide an opening for the metal testing line passing through). It is unnecessary to form the metal testing line in the periphery of the annular common electrode pattern while forming the annular common electrode pattern.

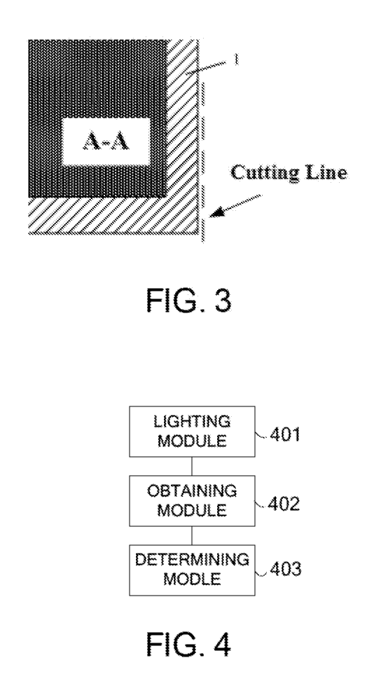

The structure of an array substrate fabricated by the array substrate fabricating method according to the embodiment of the present disclosure before the sealant is formed is shown in FIG. 3. At the corner of the side far from the data driving circuit, it includes a pixel region A-A, and a continuous and complete annular common electrode pattern 1 surrounding the pixel region A-A. On the array substrate, it is unnecessary to form a metal testing line on the outside of the common electrode pattern 1, and it is unnecessary to form an opening for the metal testing line passing through at the corner of the side of the common electrode pattern 1 far from the data driving circuit. In this way, it can reduce the complexity of the fabricating process on one hand, and it can completely avoid the package failure caused by electrochemical corrosion of the metal testing line in the reliability test on the other hand.

It is noted that the annular common electrode pattern herein may be made of metal, and may be used for accessing public high voltage VGH, or public low voltage VSS.

In an embodiment, forming a continuous and complete annular common electrode pattern surrounding a pixel region may include forming the continuous and complete annular common electrode pattern while forming the data line pattern of the array substrate in the same layer. This can reduce the thickness of the formed array substrate, facilitating in the production of light and thin products.

According to an exemplary embodiment of the present disclosure, forming the continuous and complete annular common electrode pattern in the same layer may include depositing a metal electrode layer; performing one-time patterning process on the metal electrode layer to form the data line pattern and the continuous and complete annular common electrode pattern. In this way, it is possible to reduce the patterning times, and to reduce the process complexity.

According to an exemplary embodiment of the present disclosure, a layer of metal material may be deposited by a sputtering process as the metal electrode layer. Thereafter photoresist is coated on the metal electrode layer, and exposed and developed with a mask plate, which is not transparent or not completely transparent to the positions corresponding to the data line pattern and the continuous and complete annular common electrode pattern. Thus, the photoresist which corresponds to the data line pattern to the annular common electrode pattern will not be etched. Thereafter, the photoresist is used as a protective layer to etch the metal electrode layer to form the data line pattern and the continuous and complete annular common electrode pattern.

According to an exemplary embodiment of the present disclosure, in the patterning process on the metal electrode layer when forming the data line pattern and the continuous and complete annular common electrode pattern, the metal electrode layer in the periphery of the annular common electrode pattern may be etched to form an array substrate without a metal testing line.

According to another exemplary embodiment of the present disclosure, there is further provided a device for testing eligibility of a data line of the array substrate in the embodiment of the present disclosure, that may be applied to perform the method for testing eligibility of a data line in the embodiment, and as shown in FIG. 4, the device may include a lighting module 401 arranged to light a first pixel nearest to a data driving circuit according to a first preset data voltage, and light a second pixel farthest from the data driving circuit according to a second preset data voltage, wherein the first pixel and the second pixel are both connected to the tested data line, an obtaining module 402 arranged to obtain the luminance of the first pixel and the luminance of the second pixel, and a determination module 403 arranged to determine whether the actual luminance difference between the luminance of the first pixel and the luminance of the second pixel is larger than a preset luminance difference, and determine that the tested data line is ineligible when the actual luminance difference is larger than the preset luminance difference. With the device for testing eligibility of a data line provided in the embodiment of the present disclosure, the eligibility test on the data line may be completed without the metal testing line, and the problem of package failure caused by the metal testing line can be fundamentally avoided.

According to an exemplary embodiment of the present disclosure, the magnitude of the first preset data voltage is equal to the magnitude of the second preset data voltage.

It should be noted that array substrates fabricated according to the array substrate fabricating method provided in the embodiment as well as display devices including the array substrate also falls within the scope of the present disclosure.

The above description is only specific embodiments of the present disclosure, but the scope of the present disclosure is not limited thereto. Moreover, change or replacement within the technical scope of the present disclosure, which can be easily acquired by any skilled in the art, should be encompassed within the scope of the present disclosure. Accordingly, the scope of the present disclosure should be based on the scope of the claims attached.

What is claimed is:

1. A method for fabricating an array substrate, comprising:
forming a continuous and complete annular common electrode pattern surrounding a pixel region.

2. The method according to claim 1, wherein forming a continuous and complete annular common electrode pattern surrounding a pixel region comprises forming the continuous and complete annular common electrode pattern while forming a data line pattern of the array substrate in the same layer.

3. The method according to claim 2, wherein forming the continuous and complete annular common electrode pattern while forming a data line pattern of the array substrate in the same layer comprises:
depositing a metal electrode layer; and
forming the data line pattern and the continuous and complete annular common electrode pattern by performing one-time patterning process on the metal electrode layer.

4. The method according to claim 3, wherein depositing a metal electrode layer comprises depositing a metal material using a sputtering process.

5. The method according to claim 3, further comprising:
coating a photoresist layer on the metal electrode layer; and
exposing and developing the photoresist layer with a mask plate.

6. The method according to claim 5, wherein the mask plate is not transparent or not completely transparent at positions corresponding to the data line pattern and the continuous and complete annular common electrode pattern

7. The method according to claim 3, wherein forming the data line pattern and the continuous and complete annular common electrode pattern by performing a one-time patterning process on the metal electrode layer comprises etching the metal electrode layer in the periphery of the continuous and complete annular common electrode pattern in the same-time patterning process.

8. An array substrate, comprising:
a pixel region; and
a continuous and complete annular common electrode pattern surrounding the pixel region.

9. The array substrate according to claim 8, further comprising a data line pattern, wherein the data line pattern and the continuous and complete annular common electrode pattern are formed in the same layer.

10. The array substrate according to claim 9, further comprising a metal electrode layer, wherein the data line pattern and the continuous and complete annular common electrode pattern are formed on the metal electrode layer by a one-time patterning process.

11. The array substrate according to claim 10, further comprising a photoresist layer coated on the metal electrode layer.

12. A method for testing eligibility of a data line of the array substrate according to claim 8, comprising:
lighting a first pixel nearest to a data driving circuit according to a first preset data voltage, and lighting a second pixel farthest from the data driving circuit according to a second preset data voltage, wherein the first pixel and the second pixel are both connected to the tested data line;
obtaining a luminance of the first pixel and a luminance of the second pixel;
determining whether an actual luminance difference between the luminance of the first pixel and the luminance of the second pixel is larger than a preset luminance difference; and
determining that the tested data line is ineligible when the actual luminance difference is larger than the preset luminance difference.

13. The method according to claim 12, wherein a magnitude of the first preset data voltage is equal to a magnitude of the second preset data voltage.

14. The method according to claim 12, wherein the preset luminance difference corresponds to the first preset data voltage and the second preset data voltage.

15. The method according to claim 12, wherein the first pixel and the second pixel comprise the same number of sub-pixels.

16. A device for testing eligibility of a data line of the array substrate according to claim 8, comprising:
a lighting module arranged to light a first pixel nearest to a data driving circuit according to a first preset data voltage, and light a second pixel farthest from the data driving circuit according to a second preset data voltage, wherein the first pixel and the second pixel are both connected to the tested data line;
an obtaining module arranged to obtain a luminance of the first pixel a luminance of the second pixel; and
a determination module arranged to determine whether an actual luminance difference between the luminance of the first pixel and the luminance of the second pixel is larger than a preset luminance difference, and determine that the tested data line is ineligible when the actual luminance difference is larger than the preset luminance difference.

17. The device according to claim 16, wherein a magnitude of the first preset data voltage is equal to a magnitude of the second preset data voltage.

18. The device according to claim 16, wherein the preset luminance difference corresponds to the first preset data voltage and the second preset data voltage.

19. The device according to claim 16, wherein the first pixel and the second pixel comprise the same number of sub-pixels.

20. The device according to claim 16, wherein the obtaining module is a photosensitive detection device.
